(19) United States
(12) Patent Application Publication
(10) Pub. No.: US 2022/0231476 A1
(43) Pub. Date: Jul. 21, 2022

(54) Optical Integrated Circuit

(71) Applicant: Nippon Telegraph and Telephone Corporation, Tokyo (JP)

(72) Inventors: Yuta Ueda, Musashino-shi, Tokyo (JP); Mitsuteru Ishikawa, Musashino-shi, Tokyo (JP)

(21) Appl. No.: 17/615,697

(22) PCT Filed: Jun. 3, 2019
(86) PCT No.: PCT/JP2019/021974

§ 371 Date: Dec. 1, 2021

(51) Int. Cl. H01S 5/026; G02F 1/01

(52) U.S. Cl. CPC H01S 5/026; H01S 5/125; G02F 2203/50; G02F 1/011

(57) ABSTRACT

An optical integrated circuit of the present disclosure is a monolithic optical integrated circuit formed on a substrate and includes a semiconductor laser, a 1×N optical demultiplexer, array waveguides including N waveguides, each of the N waveguides having a semiconductor optical amplifier (SOA) configured to amplify a corresponding split light beam from the semiconductor laser, and an N×1 optical multiplexer. A phase of light beams output from the SOA at input ports of the N×1 optical multiplexer is set so that the output light beams are multiplexed at an output port of the N×1 optical multiplexer in the same phase. A phase can be set by setting a length of the N waveguides and providing a phase adjuster.

### TECHNICAL FIELD

The present invention relates to an optical device and, more particularly, to an optical integrated circuit including a semiconductor laser.

### BACKGROUND ART

Semiconductor lasers are widely used in applications such as carrier light sources for optical communications, gas sensing, and machining. The required characteristics of semiconductor lasers vary depending on the applications, but, in communications and sensing, for example, light output levels are important because they affect the signal-to-noise ratio of signals. Here, a laser light output level in gas sensing using a semiconductor laser will be described.

In gas sensing, the presence (concentration), temperature, and pressure of a target gas are measured by using a light absorption spectrum unique to the gas. Specifically, a state of the gas is detected from the light absorption intensity near a specific wavelength or the width of an absorption curve by continuously sweeping the wavelength of light from a semiconductor laser. In gas sensing, a state of a gas in a certain space is often detected. Thus, a technique in which a light beam from a tunable semiconductor laser that continuously sweeps wavelengths is split into multiple beams to produce a plurality of light beams traveling through a plurality of paths in a detection target space has been adopted. Due to the difference in light absorption characteristics of each light beam in different places, spatial information of the target gas in the target space can be obtained.

A problem with the gas sensing described above is that the splitting of the light from the semiconductor laser reduces a light output level per port. If a light beam from the semiconductor laser is split into N beams, the light output level per port becomes 1/N in principle. Although a method of obtaining a plurality of light beams described above by synchronizing a plurality of tunable lasers is also conceivable, it is preferable that a single laser be used to sweep a wavelength from the perspective of controlling a sensing system. In order to compensate for the reduction in the light output level, an optical fiber amplifier can also be placed after the semiconductor laser. However, the size and power consumption required for mounting the optical fiber amplifier are problematic. Furthermore, in sensing applications, a wavelength of light from an originally used tunable light source may be different from a wavelength band for which a fiber amplification technology has been established to be used in optical communications, or the like, such as a 1.3 μm band or a 1.55 μm band.

The wavelength used for gas sensing applications as described above is special, and in a case in which compensation for light output levels is required, amplification of light is often difficult or expensive in nature. Thus, because CO₂ has strong light absorption and further H₂O which causes background absorption (noise floor) in gas sensing has weak light absorption, light having a wavelength in a 2 μm band is used in CO₂ gas sensing (Non Patent Literature 1). The 2 μm band is a wavelength band that is not used in normal optical communications, and thus amplification of light in gas sensing is limited in options and results in increased costs.

As a solution to the problem of the reduction in the output level of the semiconductor laser described above, a technique for integrating semiconductor optical amplifiers (SOAs) on a semiconductor chip of a tunable light source in an monolithic manner has been widely adopted. A semiconductor material used to make semiconductor lasers that output light having a special wavelength naturally has optical gain for light having that wavelength. Therefore, integrating a semiconductor laser and SOAs is simple from the perspective of the materials. Furthermore, SOAs are smaller than a fiber amplifier and have high energy efficiency.

### CITATION LIST

### Non Patent Literature

Non Patent Literature 1: Y Ueda., et al., “2-μm Active DBR Laser for Wide-Tuning-Range CO₂ Gas Sensing,” 2018, in the proceedings of ISLC2018, TuD3
Non Patent Literature 2: A. Hosseini, et al., “Output Formulation for Symmetrically Excited One-to-N Multimode Interference Coupler,” 2010, IEEE J STQE, vol. 16, No. 1, p. 61

### SUMMARY OF THE INVENTION

### Technical Problem

However, when a semiconductor laser is integrated with an SOA, the saturation output of the SOA is limited. The saturation output of the SOA is highly dependent on material design, and there is an upper limit on the intensity of light that can be output. In addition, a semiconductor design suitable for an SOA with high output may be different from a semiconductor design suitable for achieving optical gain of semiconductor lasers. From a separate approach to semiconductor design, there is demand for high saturation output for SOAs. The present invention has been conceived taking the above-described problems into account, and aims to provide an optical integrated circuit capable of increasing a substantial saturation output level of an SOA and increasing the output of a semiconductor laser.

### Means for Solving the Problem

A first aspect of the present disclosure is a monolithic optical integrated circuit formed on a substrate, the optical integrated circuit including a semiconductor laser formed on the substrate, a 1×N optical demultiplexer configured to split a light beam output from the semiconductor laser into N beams, array waveguides including N waveguides connected to N outputs of the optical demultiplexer, each of the array waveguides having a semiconductor amplifier (SOA) configured to amplify a corresponding split light beam from the semiconductor laser, and an N×1 optical multiplexer connected to the N waveguides, in which a phase of the output light beams from the SOA at input ports of the N×1 optical multiplexer is set so that the output light beams are multiplexed at an output port of the N×1 optical multiplexer in the same phase.

Here, if the phase of the light beams is defined to be delayed with respect to a propagation direction of the light beams (to have a smaller phase angle), the phase of the output light beams may be set so that a phase at the input ports on outer sides of the N×1 optical multiplexer is advanced by a predetermined amount of phase α° with respect to the input ports at the center of the N×1 optical multiplexer. In addition, the predetermined amount of phase α may be determined based on the number of ports N of the optical multiplexer, and increase symmetrically from the input ports at the center to the input ports on the outer sides.

For the above-described setting of the phase, a length of at least one waveguide of the N waveguides from the 1×N optical demultiplexer to the N×1 optical multiplexer may be different from a length of another waveguide among the N waveguides.

The phase of the output light beams from the SOAs may be set based on a drive current value of the SOAs.

Each of the array waveguides may include a phase adjuster on an output side of a corresponding SOA, and each phase may be set so that the output light beams are multiplexed at the output port of the N×1 optical multiplexer in the same phase.

The phase adjuster may include an electrode configured to inject a current into the N waveguides or to change a temperature of the N waveguides.

A wavelength of the output light beam from the semiconductor laser may be in a range of 1950 nm to 2150 nm. Preferably, the semiconductor laser is applicable to gas sensing.

### Effects of the Invention

An optical integrated circuit that increases an output of a semiconductor laser can be provided.

### BRIEF DESCRIPTION OF DRAWINGS

FIG. 1 is a diagram illustrating a configuration of a first embodiment of an optical integrated circuit of the present disclosure.

FIG. 2 is a diagram illustrating an example of a cross-sectional structure of a waveguide in a portion of the optical integrated circuit of the present disclosure.

FIG. 3 is a diagram illustrating a cross section of a waveguide structure constituting a phase adjuster of the optical integrated circuit.

FIG. 4 is a diagram illustrating a configuration of a second embodiment of the optical integrated circuit of the present disclosure.

### DESCRIPTION OF EMBODIMENTS

An optical integrated circuit of the present disclosure splits a light beam from a semiconductor laser into N beams and amplifies each of the light beams having an intensity of 1/N with SOAs at a saturation output level of Ps. When an optical multiplexer having N×1 ports multiplexes the amplified light beams from the SOAs, the light beams being amplified by the SOAs to a saturation output level, the optical output of N·Ps can be obtained. The SOAs operate to substantially increase the saturation output level.

The optical integrated circuit of the present disclosure is a monolithic optical integrated circuit formed on a substrate and includes a semiconductor laser, a 1×N optical demultiplexer, an array waveguide, and an N×1 optical multiplexer. The array waveguide is an array waveguide including N waveguides, each of the N waveguides having a semiconductor optical amplifier (SOA) that amplifies a corresponding split light beam from the semiconductor laser. The phase of light beams output from the SOAs at the input ports of the N×1 optical multiplexer is set so that the output light beams are multiplexed at the output port of the N×1 optical multiplexer in the same phase. The setting of the phase can be implemented by setting a length of the N waveguides. At this time, the phase of the light beams output from the SOAs at the input port of the N×1 optical multiplexer is set in accordance with the port position to have a phase distribution in which the phase at the input ports on the outer sides (both sides) is advanced by a predetermined amount of phase α° with respect to the input ports at the center of the N×1 optical multiplexer. The amount of phase advancement increases in left-right symmetry from the input ports at the center to the input ports on the outer sides. In addition, the predetermined amount of phase is determined based on a configuration such as the number of ports of the optical multiplexer.

The above-described setting of a phase can also be implemented by adjusting a drive current of the SOAs. The optical integrated circuit of the present disclosure can be used as a high-output light source. Furthermore, a phase adjuster may be provided on the N waveguides. Hereinafter, embodiments of the optical integrated circuit of the present disclosure will be described in detail.

### First Embodiment

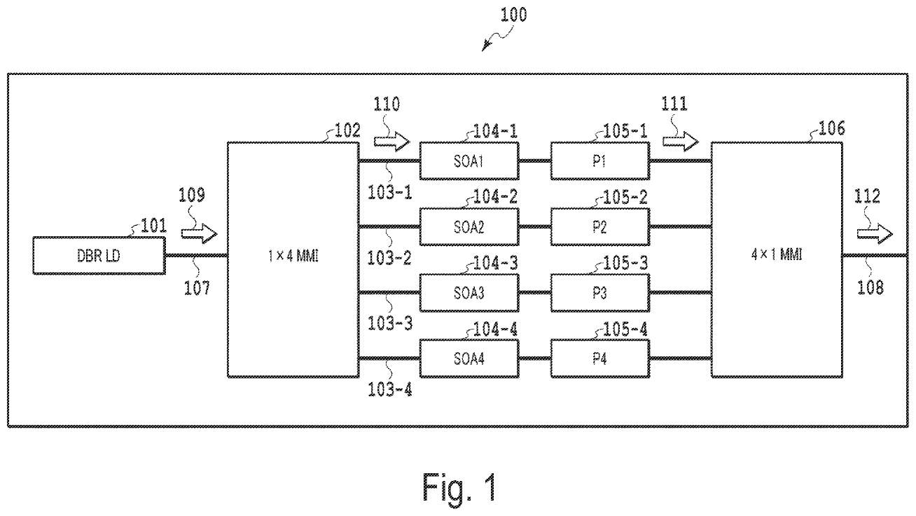

FIG. 1 is a diagram illustrating a configuration of a first embodiment of the optical integrated circuit of the present disclosure. An optical integrated circuit 100 in FIG. 1 is formed entirely on a substrate, and a distributed Bragg reflector (DBR)-type tunable light source and a plurality of SOAs, and the like are integrated together in a monolithic manner. It should be noted that FIG. 1 is a top view of a substrate surface viewed vertically, conceptually illustrating the following functional portions of the optical integrated circuit as blocks without reflecting actual sizes and shapes on the substrate. A high-output semiconductor laser (a laser diode or an LD) is realized by a 2 μm band tunable light source for the optical integrated circuit 100 of FIG. 1.

InP, for example, is selected for the substrate, and a DBR-type tunable light source (DBR LD) 101 which emits light having a wavelength in the 2 μm band is formed as a semiconductor laser on the substrate. The DBR LD 101 is not limited for CO₂ as long as it is applicable to gas sensing. An output light beam 109 of the DBR LD 101 is input to the a 1×4 optical demultiplexer 102 to be split into four beams at output ports. The output ports of the optical demultiplexer 102 are coupled to waveguides 103-1 to 103-4 of the array waveguide. The split light beams 110 coupled to each of the waveguides 103-1 to 103-4 are further coupled to corresponding semiconductor optical amplifiers (SOA 1 to SOA 4) 104-1 to 104-4. Electrodes are disposed on each of the waveguides as phase adjusters (P1 to P4) 105-1 to 105-4, which will be described below. A 4×1 optical multiplexer 106 multiplexes light beams 111 of which the phases have been adjusted on each of the waveguides, and outputs a multiplexed output light beam 112 from an output port 108. As described above, it should be noted that the SOAs and the phase adjusters are formed to be integrated with each of the waveguides 103-1 to 103-4 substantially along the waveguides and do not occupy a larger area compared to the waveguides 103-1 to 103-4 as illustrated in FIG. 1.

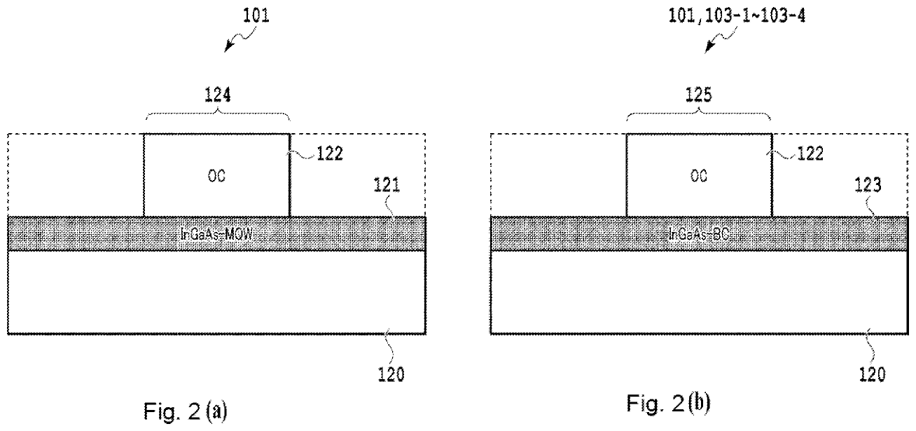

FIG. 2 is a diagram illustrating an example of a cross-sectional structure of a waveguide in a portion of the optical integrated circuit of the present disclosure. FIGS. 2(a) and 2(b) both illustrate cross-sectional views taken perpendicular to the waveguide direction (length direction) of the waveguide. FIG. 2(a) illustrates a cross-sectional view of a waveguide structure in an active region of the DBR LD 101. The DBR LD has an active region and an inactive region that is a DBR region before and after the active region in the waveguide direction, and each region is known as being able to be composed of one continuous waveguide. In the active region of FIG. 2(a), a strain InGaAs multiple quantum well layer 121 (InGaAs-QW) including strain InGaAs with an adjusted amount of strain is provided as an optical gain layer on an InP substrate 120. The optical gain layer has a photoluminescent wavelength set in the 2 μm band. An overcladding (OC) 122 made of InP is stacked on the InP substrate 120 and the strain InGaAs-QW layer 121, and it is removed by a suitable etching step with a portion of the overcladding left as indicated by the dashed lines. This forms a so-called ridge-type waveguide 124.

FIG. 2(b) illustrates a cross-sectional view of a waveguide structure in the inactive region of the DBR LD 101. A vertical mode control waveguide portion and a DBR waveguide portion that are inactive regions of the DBR laser to select an oscillation wavelength are set as a bulk-type InGaAs core (InGaAs-BC) 123 formed on the InP substrate 120. The overcladding (OC) 122 made of InP is stacked on the InP substrate 120 and the bulk-type InGaAs core 123. Similarly to the active region, a ridge-type waveguide 125 is formed, and the ridge-type waveguide 125 is connected to the front and rear of the ridge-type waveguide 124 in the waveguide direction of FIG. 2(a).

An InGaAs bulk layer grown without a strain on the InP substrate is transparent for light of the 2 μm band. Light emitted from the DBR LD 101 of FIG. 1 is guided through a waveguide 107 formed as the InGaAs-BC that is made of the same semiconductor material as the vertical mode control waveguide and the DBR waveguide portion illustrated in FIG. 2(b) described above, and split by the 1×4 optical demultiplexer 102 also formed as an InGaAs-BC. Here, the optical demultiplexer 102 employs a multi-mode interference waveguide (MMI) with 1×4 ports. The number of splits by the MMI waveguide is not limited to four, and is arbitrary. Further, the optical demultiplexer 102 may be configured as a so-called star coupler, for example, with a slab waveguide. The optical demultiplexer 102 needs not have wavelength selectivity because it is only required to split light output from the DBR LD.

The light beams 110 that have been split into four beams by the optical demultiplexer 102 are coupled to the array waveguides 103-1 to 103-4 formed as the InGaAs-BC, similar to that of FIG. 2(b). Each of the split light beams is coupled to a corresponding one of the SOAs 104-1 to 104-4. The SOAs 104-1 to 104-4 are formed of InGaAs-MQWs, which is the same material as the optical gain portion of the active region of the DBR LD 101, as illustrated in FIG. 1(a). In the optical integrated circuit 100 of the present disclosure, no special design is performed to improve the saturation output level of the SOAs, and conditions for the semiconductor to create existing DBR LDs can be utilized as they are. The optical integrated circuit 100 has electrodes disposed as the phase adjusters 105-1 to 105-4 (P1 to P4) on each of the waveguides 103-1 to 103-4 after the SOAs.

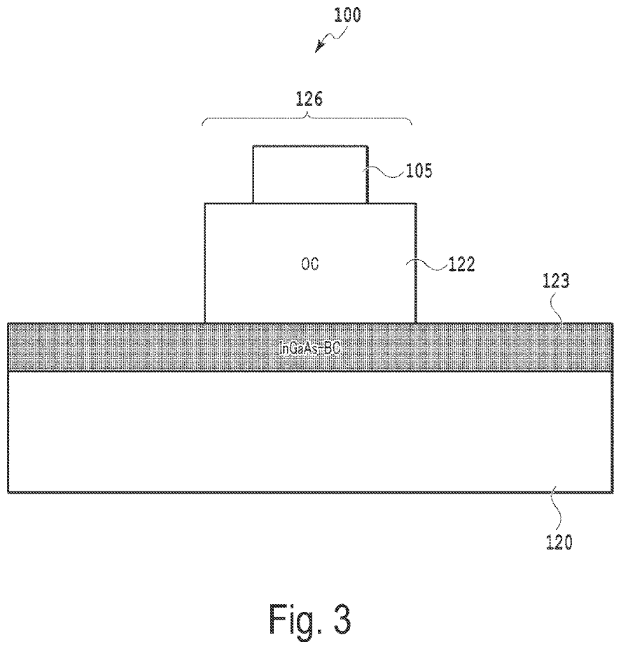

FIG. 3 is a diagram illustrating a cross section of a waveguide structure constituting a phase adjuster of the optical integrated circuit. In the optical integrated circuit 100, the waveguides included in the phase adjusters 105-1 to 105-4 are the same as each of the waveguides 103-1 to 103-4 of an array waveguide formed as the InGaAs-BC as illustrated in FIG. 2(b), and constitutes a ridge waveguide 126. The difference from FIG. 2(b) is that the phase adjustment electrode 105 is provided on the OC 122. In the top view of FIG. 1, the phase adjusters 105-1 to 105-4 are illustrated as if they were larger than each waveguide, but actually, electrodes are formed on the OC of the array waveguide. Each of the waveguides 103-1 to 103-4 of the array waveguide is connected to the optical multiplexer 106 with N×1 ports. The optical multiplexer 106 can be configured as an MMI, similarly to the optical demultiplexer 102. In the present embodiment, the optical multiplexer 106 has four input ports because the optical demultiplexer 102 splits output laser beams into four beams, and the propagation light beams from each of the waveguides 103-1 to 103-4 are multiplexed at the output port 108 of the optical multiplexer 106. As described above, the waveguides 103-1 to 103-4 of the array waveguide are continuously connected from the output ports of the optical demultiplexer 102 to the corresponding input ports of the optical multiplexer 106, respectively, and thus the waveguides are set to have the same length in the present embodiment.

The phase adjustment electrodes 105 inject a current into each of the waveguides 103-1 to 103-4 of the array waveguide, for example, to change the refractive index of the respective waveguides. As a result, the phase of the light beams guided through each of the waveguides and amplified by the SOAs changes. In addition, the refractive index of the waveguides may also be changed by injecting a current through the phase adjustment electrodes 105 and changing a temperature of the waveguides. Although not illustrated in FIG. 3, a temperature varying means connected to the electrodes 105, such as a heater, for example, may be provided.

It is generally known that, in order to collect light beams into one output port of an MMI with N×1 ports, the phases of the light beams input into N input ports are required to be in a fixed relationship, as will be described below (e.g., Non Patent Literature 2). Thus, an “optical path length” of each of the waveguides 103-1 to 103-4 from the 1×4 optical demultiplexer 102 to the 4×1 optical multiplexer 106 may be set so that split light beams propagating through each of waveguides are multiplexed at the output port 108 of the optical multiplexer 106 in the same phase. In other words, the phase of each of split light beams at the input ports of the 4×1 optical multiplexer 106 may be set so that the light beams are multiplexed at the output port 108 of the optical multiplexer 106 in the same phase.

Brief conditions for setting the phase of the split light beams multiplexed at the output port 108 in the same phase are as follows. The number of splits N of the optical demultiplexer and the optical multiplexer is a natural number equal to or greater than 2. When the positions of the input ports of the optical multiplexer are considered, the phase at the input ports on the outer sides is advanced by a predetermined amount of phase α° with respect to the input ports at the center. The amount of phase gradually increases from the center to the outer side in left-right symmetry. Although the predetermined amount of phase α° depends on the number of splits N and the specific design method of the optical multiplexer, for example, the phase can be advanced by 90° when N is equal to 4, and 270° when N is equal to 8. The number of ports may be odd or even.

Thus, the optical integrated circuit of the present disclosure is a monolithic optical integrated circuit formed on the substrate, the optical integrated circuit including the semiconductor laser 101 formed on the substrate, the 1×N optical demultiplexer 102 that splits the output light beam 109 from the semiconductor laser into N light beams, the array waveguides 103-1 to 103-4, and the N×1 optical multiplexer 106 connected to the N waveguides. Here, the array waveguides 103-1 to 103-4 include the N waveguides connected to the N outputs of the optical demultiplexer, each of the array waveguides having the semiconductor optical amplifiers (SOAs) 104-1 to 104-4 for amplifying corresponding split light beams from the semiconductor laser. In the optical integrated circuit of the present disclosure, the phase of light beams 111 output from the SOAs at the input ports of the N×1 optical multiplexer is set so that the output light beams are multiplexed at the output port 108 of the N×1 optical multiplexer in the same phase.

Assuming that a saturation output level of the SOAs 104-1 to 104-4 is Ps, the optical output of the output port 108 of the optical integrated circuit 100 having the 1×4 optical demultiplexer 102 and the 4×1 optical multiplexer 106 illustrated in FIG. 1 may be four times Ps. If the number of splits of the optical demultiplexer and the optical multiplexer is increased to 8, for example, the output can be eight times Ps as long as there is no other limiting factor. In the optical integrated circuit of the first embodiment illustrated in FIG. 1, a setting of a phase of each split light beam is performed by the phase adjusters, with the lengths of the array waveguides set to be the same. It is performed by injecting a current into the waveguides via the phase adjustment electrodes serving as the phase adjusters to change the refractive index of the waveguides. However, the setting of the phase of each split light beam can also be implemented using a simpler approach, as will be described in the embodiment below.

### Second Embodiment

In the optical integrated circuit of the first embodiment, the electrodes for injecting a current into each of the waveguides of the array waveguides through which split light beams propagate are provided as the phase adjusters. In order to adjust the phase of the split light beams, the length of each waveguide of the array waveguides may be set in advance so that the split light beams are multiplexed at the output port 108 of the optical multiplexer 106 in the same phase. If conditions to achieve multiplexing in the same phase by the optical multiplexer to be used are known in advance, a length of the waveguide connected to each input port of the optical multiplexer can be set to meet the conditions. That is, by appropriately setting lengths of the waveguides connecting the optical demultiplexer to the optical multiplexer, it is possible to achieve multiplexing at the output port of the optical multiplexer in the same phase.

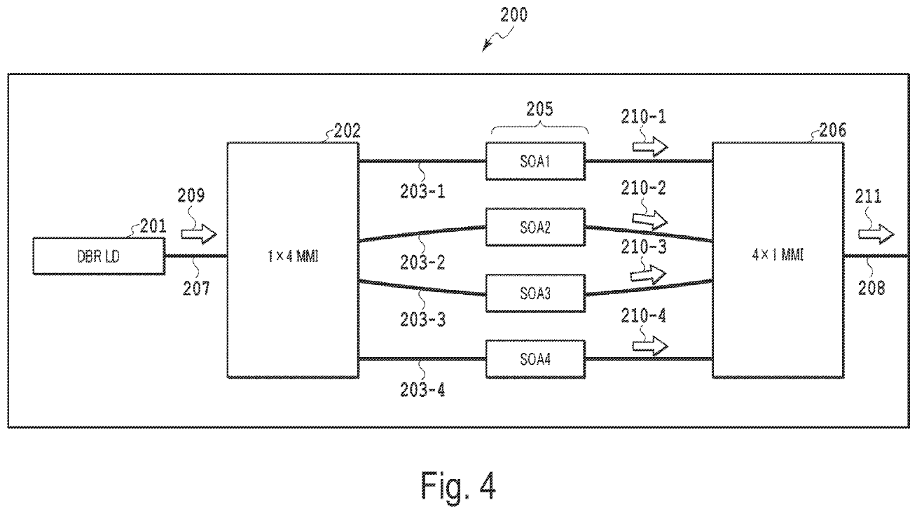

FIG. 4 is a diagram illustrating a configuration of a second embodiment of the optical integrated circuit of the present disclosure. An optical integrated circuit 200 in FIG. 4 has substantially the same configuration as the optical integrated circuit illustrated in FIG. 1. In other words, a DBR LD 201 formed on a substrate, an optical demultiplexer 202, four waveguides 203-1 to 203-4 that are array waveguides, SOAs 205 on each of the waveguides, and an optical multiplexer 206 are provided. The differences are that the optical integrated circuit 200 of the second embodiment in FIG. 4 does not include a phase adjuster and lengths of the four waveguides 203-1 to 203-4 connecting the optical demultiplexer 202 to the optical multiplexer 206 vary.

Varying the lengths of the four waveguides 203-1 to 203-4 is equivalent to providing the phase adjusters of the first embodiment. According to the configuration of the optical integrated circuit 200 of the present embodiment, an external signal is not required for phase adjustment, and thus a simpler configuration is achieved in terms of control of the semiconductor laser compared to the first embodiment.

In the optical multiplexer configured as an MMI with N×1 ports, a phase of light changes symmetrically with respect to the structural center of the MMI. Specifically, in a case of a 4×1 MMI, a phase at the two ports at the center connected to the waveguides 203-2 and 203-3 is set to zero and a phase at the two ports at the outer sides connected to the waveguides 203-1 and 203-4 is set to 90°. At this time, if the intensities of four light waves 210-1 to 210-4 amplified by the SOAs are completely equal, the four light waves are collected at the output port 208 of the 4×1 MMI with the highest efficiency, and thus an output intensity four times higher than that of the output light beams from the SOAs is obtained. Here, a phase of a light wave is defined such that the phase of the light beam in the space changes in the negative direction with respect to the propagation distance.

In a case in which a 1×4 (or 4×1) MMI with four ports is used as an optical demultiplexer and an optical multiplexer as in the first embodiment and the second embodiment, a phase of four split light beams from the optical demultiplexers 102 and 202 is delayed at the two ports at the center of the MMI at which the phase is advanced relative to the two ports provided structurally at the outer sides of the MMI. Furthermore, the phases of the light beams at the two ports at the center may be delayed so that the split light beams that have been amplified by the optical multiplexers 106 and 206 are collected at the output ports 108 and 208 with high efficiency. However, it is not necessary to align the phases of the light waves in each of the optical demultiplexers and the optical multiplexers independently of each other, and the phases of the light waves from the SOAs may be eventually set at the input ports of the optical multiplexers 106 and 206 so that they are multiplexed at the output ports of the optical multiplexers in the same phase.

Conditions for setting the phases based on the lengths of the waveguides are as described above, and the number of splits N of the optical demultiplexers and the optical multiplexers is a natural number equal to or greater than 2. When the positions of the input ports of the optical multiplexer 206 are considered, the phase at the input ports on the outer sides is advanced by a predetermined amount of phase α° with respect to the input ports at the center. The amount of phase gradually increases from the center to the outer sides in left-right symmetry. The predetermined amount of phase α° depends on the number of splits N and the specific design method of the optical multiplexer, and for example, the phase can be advanced by 90° when N is equal to 4, and 270° when N is equal to 8.

In order to realize the above-described phase difference as a difference in length of the array waveguides, the waveguides 203-2 and 203-3 at the center are slightly bent to serve as waveguides having a slightly longer length than the array waveguides 203-1 and 203-4 on the outer sides as illustrated in FIG. 4. Thus, the phases of the light beams that are guided through the array waveguides 203-1 and 203-4 can be compensated for. Because the phase difference is less than or equal to 360° (2π), the difference in length of the waveguides achieved by bending of the waveguides at the center is less than or equal to the wavelength of target light.

In the case of the optical integrated circuit 200 of the present embodiment, the oscillation wavelength of the DBR LD is in the 2 μm band, and at this time, the refractive index of the InP-based semiconductor is approximately 3.5. Thus, the difference in length of the two bent waveguides 203-2 and 203-3 at the center and the straight waveguides 203-1 and 203-4 on the outer sides is approximately 600 nm at most. The compensation for the optical phases of the optical integrated circuit according to the present embodiment is useful when an error in the phases of the light beams guided through the array waveguide waveguides 203-1 to 203-4 is sufficiently reduced in manufacturing, in consideration of changes as well in the optical phases associated with optical amplification by the four SOAs (SOA 1 to SOA 4) on each of the waveguides.

### Third Embodiment

In the two embodiments described above, phase adjustment (phase compensation) is performed so that the split light beams amplified by the SOAs are multiplexed at the output port of the optical multiplexer in the same phase by providing electrodes as phase adjusters and setting a difference in length of the array waveguides depending on the positions of the ports of the optical multiplexer. As another simpler method, phase adjustment can also be made with a configuration in which each of the waveguides has the same length and no phase adjuster is provided. Specifically, the phase of light beams guided through the SOAs and the array waveguides can be eventually controlled by varying an amount of current injected into the SOAs for each waveguide and using a carrier density and a temperature change resulting from current heat generation within the SOAs. In other words, in a state in which the phase adjusters 105-1 to 105-4 are removed from the configuration of the optical integrated circuit 100 illustrated in FIG. 1, it is only required to adjust each drive current of the SOAs 104-1 to 104-4. In the present embodiment, each SOA also serves as a phase adjuster in the first embodiment.

The present embodiment is useful in a case in which an amount of change in a light output level when a current to be injected to the SOAs is changed is low and a change in a phase of light beams guided by the SOAs is significant to satisfy the conditions for multiplexing at the optical demultiplexer and the optical multiplexer having N×1 ports described in the configuration of the second embodiment. Specifically, the useful application is a case in which the output light level from the SOAs is close to the saturation output Ps thereof, and the embodiment can be used in a case in which a change in the output level is small due to the output saturation even if the drive current of the SOAs is changed, and the phase fluctuation is relatively large. According to the optical integrated circuit of the present embodiment, an optical integrated circuit that can increase the substantial saturation output level of the SOAs and increase the output of the semiconductor laser is provided in a simple configuration in which the array waveguides between the optical demultiplexer and the optical multiplexer are set to have the same length with no phase adjuster.

As described in detail above, with the optical integrated circuit of the present disclosure, the SOAs disposed between the optical demultiplexer and the optical multiplexer having the 1×N (or N×1) configuration can be used near at the saturation output level, and a high output N times greater than the saturation output level of the SOAs can be obtained as the final multiplexing output. The number of ports of the optical demultiplexer and the optical multiplexer is not limited to only four as described in the above embodiments. If a mode of a phase change in an optical signal at each port of the optical demultiplexer and the optical multiplexer is known in advance, a phase at the array waveguides can be set to compensate for the difference in phase of the optical signal at the input ports of the optical multiplexer caused by the phase change. Condition for setting the phase may be obtained as an amount of phase compensation in accordance with the configuration such as the number of ports of the optical demultiplexer and the optical multiplexer to be used.

It is a matter of course that, although the optical integrated circuit of the present disclosure is useful as a light source in gas sensing, or the like, it is not limited thereto, and can be applied to fields in which optical output from a wavelength sweep light source at a high output level is required.

### INDUSTRIAL APPLICABILITY

The present invention can be used in sensing. More specifically, it can be utilized for a laser light source used in a gas sensing system.

1. A monolithic optical integrated circuit formed on a substrate, comprising:
a semiconductor laser formed on the substrate;
an optical demultiplexer configured to split a light beam output from the semiconductor laser into N beams;
array waveguides including N waveguides connected to N outputs of the optical demultiplexer, each of the array waveguides having a semiconductor amplifier (SOA) configured to amplify a corresponding split light beam from the semiconductor laser; and
an optical multiplexer connected to the N waveguides,
wherein a phase of the output light beams from the SOA at input ports of the optical multiplexer is set so that the output light beams are multiplexed at an output port of the optical multiplexer in the same phase.

2. The optical integrated circuit according to claim 1,
wherein the phase of the output light beams is set so that a phase at the input ports on outer sides of the optical multiplexer is advanced by a predetermined amount of phase α° with respect to the input ports at the center of the optical multiplexer.

3. The optical integrated circuit according to claim 2,
wherein the predetermined amount of phase α is determined based on the number of ports N of the optical multiplexer, and increases symmetrically from the input ports at the center to the input ports on the outer sides.

4. The optical integrated circuit according to claim 2,
wherein a length of at least one waveguide of the N waveguides from the optical demultiplexer to the optical multiplexer is different from a length of another waveguide among the N waveguides.

5. The optical integrated circuit according to claim 2,
wherein the phase of the output light beams from the SOA is set based on a drive current value of the SOA.

6. The optical integrated circuit according to claim 1,
wherein each of the array waveguides includes a phase adjuster on an output side of the corresponding SOA, and each phase is set so that the output light beams are multiplexed at the output port of the optical multiplexer in the same phase.

7. The optical integrated circuit according to claim 6,
wherein the phase adjuster includes an electrode configured to inject a current into the N waveguides or to change a temperature of the N waveguides.

8. The optical integrated circuit according to claim 1,
wherein a wavelength of the output light beam from the semiconductor laser is in a range of 1950 nm to 2150 nm.

9. The optical integrated circuit according to claim 3,
wherein a length of at least one waveguide of the N waveguides from the optical demultiplexer to the optical multiplexer is different from a length of another waveguide among the N waveguides.

10. The optical integrated circuit according to claim 3,
wherein the phase of the output light beams from the SOA is set based on a drive current value of the SOA.

11. The optical integrated circuit according to claim 2,
wherein a wavelength of the output light beam from the semiconductor laser is in a range of 1950 nm to 2150 nm.

12. The optical integrated circuit according to claim 3,
wherein a wavelength of the output light beam from the semiconductor laser is in a range of 1950 nm to 2150 nm.

13. The optical integrated circuit according to claim 4,
wherein a wavelength of the output light beam from the semiconductor laser is in a range of 1950 nm to 2150 nm.

14. The optical integrated circuit according to claim 5,
wherein a wavelength of the output light beam from the semiconductor laser is in a range of 1950 nm to 2150 nm.

15. The optical integrated circuit according to claim 6,
wherein a wavelength of the output light beam from the semiconductor laser is in a range of 1950 nm to 2150 nm.

16. The optical integrated circuit according to claim 7,
wherein a wavelength of the output light beam from the semiconductor laser is in a range of 1950 nm to 2150 nm.
